(19) United States
(12) Patent Application Publication
(10) Pub. No.: US 2012/0152726 A1
(43) Pub. Date: Jun. 21, 2012

(54) METHOD AND APPARATUS TO PRODUCE HIGH DENSITY OVERCOATS

(76) Inventors: Samuel D. HARKNESS IV, Berkeley, CA (US); Terry Bluck, Santa Clara, CA (US); Michael A. Russak, Pleasanton, CA (US); Quang N. Tran, San Jose, CA (US)

(21) Appl. No.: 13/094,779

(22) Filed: Apr. 26, 2011

Related U.S. Application Data
(60) Provisional application No. 61/424,550, filed on Dec. 17, 2010.

(51) Int. Cl. C23C 14/35

(52) U.S. Cl. 204/192.12; 204/298.16

(57) ABSTRACT

A deposition system is provided, where conductive targets of similar composition are situated opposing each other. The system is aligned parallel with a substrate, which is located outside the resulting plasma that is largely confined between the two cathodes. A “plasma cage” is formed wherein the carbon atoms collide with accelerating electrons and get highly ionized. The electrons are trapped inside the plasma cage, while the ionized carbon atoms are deposited on the surface of the substrate. Since the electrons are confined to the plasma cage, no substrate damage or heating occurs. Additionally, argon atoms, which are used to ignite and sustain the plasma and to sputter carbon atoms from the target, do not reach the substrate, so as to avoid damaging the substrate.

### CROSS-REFERENCE TO RELATED APPLICATIONS

This application claims priority from U.S. Provisional Patent Application No. 61/424,550, filed on Dec. 17, 2010, the entirety of which is incorporated herein by reference.

### BACKGROUND

1. Field

This application relates to the art of forming thin films, such as by physical vapor deposition (PVD). More specifically, this application relates to forming thin film, such as diamond-like coating (DLC) on substrates, such as magnetic disks used in hard drives.

2. Related Art

Hard drive disks are fabricated by forming various thin-film layers over a round substrate. Some of these layers include magnetic materials that is used as the memory medium, and some of these layers are formed as protection. Finally, a lubricant layer is deposited on the surface of the disk to enable smooth flying of the magnetic read/write head.

As recording densities intensify, new technologies have emerged to enable recording upon nanometer-sized granular medium designs. As always, thin but reliable tribological layers are sought, that provide a robust interface with the lubricant layer and a minimal detraction from reading/writing capabilities. Additionally, some in the industry seek a solution to writing very high anisotropy magnetic material (required to stabilize miniscule grains from random reversal due to thermal agitation) in the form of thermal assist. This is currently at the laboratory level, but the concept yields great promise for extending the limit of areal density well past 1 Tb/in².

One formidable obstacle to realizing this design in manufacturing is the reality that current hydrogenated diamond like carbon (DLC) overcoats are likely to become graphitized under the persistent exposure to elevated temperatures and, thus, lose their protective quality. Using current overcoat application paradigms (e.g., ion beam chemical vapor deposition (CVD)), however, it is required that hydrogen be added reactively to the growth process to pacify the high density of dangling bond defects incumbent in the processes. Many have considered filtered cathodic arc (FCA) as an alternative process capable of producing high density, high quality DLC films without the addition of process hydrogen.

With increasing film density toward the limit of 3.51 g/cm³ (sp³ diamond) comes the enhanced ability to reduce the overcoat from typical thicknesses of 3 nm to 2 nm without the sacrifice of increased exposure to corrosion. It is understood to be the high flux density of positively ionized carbon atoms at specific ranges of adsorption energy that enables the highly sp³-structured resultant film. Unfortunately, the FCA technique brings with it inherent problems including compatibility with the installed base of disc processing equipment, a process prone to high counts of particulates, and poor scalability to accommodate various sizes of substrates and carrier panels.

Consequently, a solution is required to enable fabrication of high quality sp³-structured DLC using a process that readily lands itself to commonly available disk manufacturing equipment.

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Various embodiments of the invention enable a new adaptation of an existing technology to deliver the same scope of benefits as reviewed for FCA overcoats (generally called ta-C films or tetrahedral amorphous carbon) without the listed liabilities.

Embodiments of the invention enable high deposition rate, high target utilization, controlled plasma interaction with the growing film, and reduced neutral recoil or negative ion induced damage on the substrate. The embodiments are useful for various applications, and are especially beneficial for depositing DLC coating. Other examples where embodiments of the invention can be beneficial include ITO (Indium Tin Oxide) deposition of polymeric substrates (OLEDs, etc.), high quality TCO (transparent conductive oxide with high transmissivity and low resistivity (T, ρ), such as ZnO:Al, ITO, etc., deposition of a-Si:H (hydrated amorphous silicon), improved CIGS/CIS sputter quality, Li/LiCoO3 deposition for improved Li-ion battery capacity, etc.

A deposition system is provided, where conductive targets of similar composition are situated opposing each other. The system is aligned parallel with a substrate, which is located outside the resulting plasma that is largely confined between the two cathodes. That is, embodiments of the invention generate a “plasma cage” wherein the carbon atoms collide with accelerating electrons and get highly ionized. The electrons are trapped inside the plasma cage, while the ionized carbon atoms are deposited on the surface of the substrate. Since the electrons are confined to the plasma cage, no substrate damage or heating occurs. Additionally, the embodiments are designed such that argon atoms, which are used to ignite and sustain the plasma and to sputter carbon atoms from the target, do not reach the substrate, so as to avoid damaging the substrate.

According to aspects of the invention, a facing target sputtering (FTS) has been developed to enable high arrival rates of ionized atoms to a substrate situated remotely from the plasma. In the application for depositing ta-C films, the highly ionized atoms are highly ionized carbon atoms. Specifically, a minimum of 30 eV adatom energy is believed to be required for sp³ formation. Therefore, embodiments of the invention are structured to deliver 30-100 eV adatom energy, wherein the optimal energy is 54 eV.

Embodiments of the invention enable the fabrication of DLC densities greater than 2.7 g/cm³ and without the incorporation of process hydrogen.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 illustrates a system according to an embodiment of the invention;

FIG. 2 illustrates a cross section of one of chambers 140;

FIG. 3 is a simplified schematic illustrating a combination source according to an embodiment of the invention, viewed from inside of the chamber, as shown in broken-line arrows A-A in FIG. 2.

FIG. 4 is a plot of X-ray reflectometry (XRR) pattern for representative DLC film grown on a NiP/Al disc substrate. Fitting analysis results in the determination that this film is high density (˜2.9 g/cm3), with a thickness of 22 nm and a roughness conformal to the substrate below (<0.5 nm).

### DETAILED DESCRIPTION

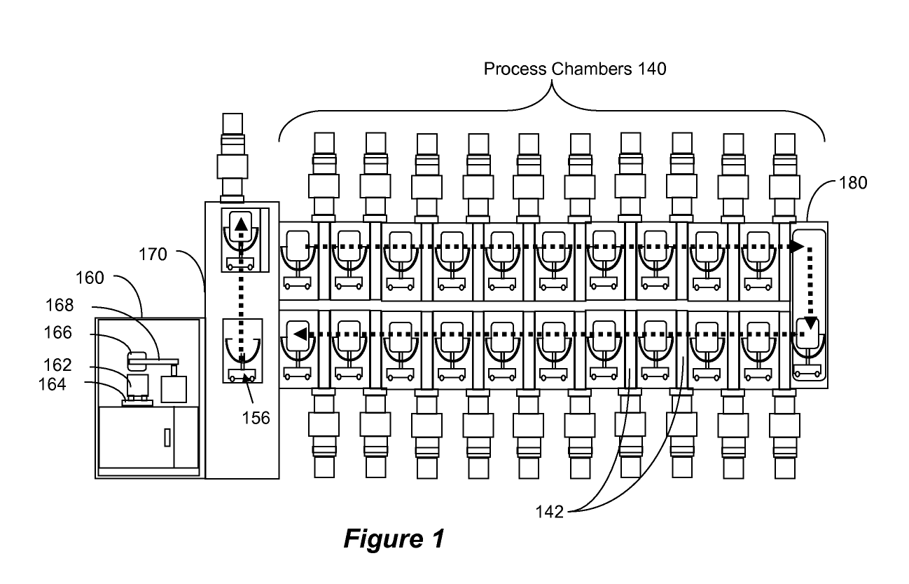

A detailed description will now be given of a processing system according to embodiments of the invention. FIG. 1 illustrates a system for high capacity sequential processing of substrates, which employs unique sputter deposition sources. The system is especially beneficial for fabrication of disks for hard disk drives, but can also be used for fabrication of other devices, such as solar cells, light emitting diodes, etc. In one embodiment, the invention is implemented on an Intevac 200 Lean™ disc-sputtering machine, available from Intevac of Santa Clara, Calif. The system is generally constructed of several identical processing chambers 140 connected in a linear fashion, such that substrates can be transferred directly from one chamber to the next. While in the embodiment of FIG. 1 two rows of chambers are stacked one on top of the other, this is not necessary, but it provides a reduced footprint.

A front end module 160 includes tracks 164 for transporting cassettes 162 containing a given number of substrates 166. The front end unit 160 maintains therein a clean atmospheric environment. A robotic arm 168 or other system (e.g., knife edge lifter) removes substrates 166, from the cassette 162 and transfers them into a loading module 170. Loading module 170 loads each substrate 166 onto a substrate carrier 156, and moves the substrate 166 and carrier 156 into a vacuum environment. According to another implementation, the loading module is already in vacuum environment, so that the loading of the substrate onto the carrier is done in vacuum environment.

In the embodiment of FIG. 1, each carrier is shown to hold a single substrate, but other embodiments can utilize carriers that hold two substrates, either in tandem or back to back. Thereafter the carriers 156 and substrates 166 traverse the processing chambers 140, each of which operates in vacuum and is isolated from other processing chambers by gate valves 142 during processing. The motion of the carrier 156 is shown by the broken-line arrows. Once processing is completed, the substrate 166 is removed from the carrier 156 and is moved to an atmospheric environment and placed in the cassette 162 by robot arm 168.

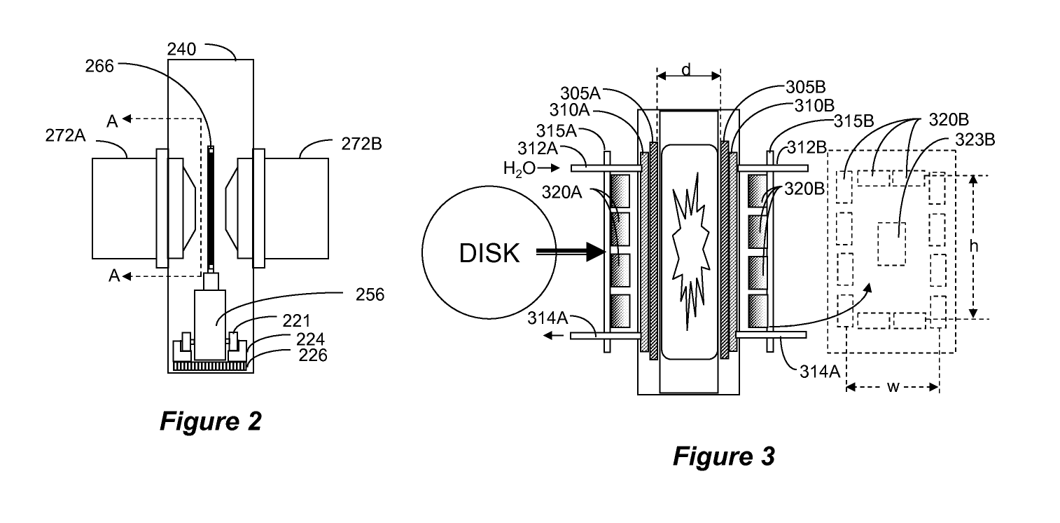

In FIG. 1, each of chambers 140 can be tailored to perform a specific process. For example, some chambers may be fitted with a heater to heat or anneal the substrate; some chambers may be fitted with standard sputtering source to deposit magnetic material on the surface of the substrate, etc. FIG. 2 illustrates a cross section of one of chambers 140 which is fitted with two sputtering sources 272A and 272B, according to an embodiment of the invention. Substrate 266 is shown mounted vertically onto carrier 256. Carrier 256 has wheels 221, which ride on tracks 224, but the reverse can also be implemented, i.e., the carrier may have tracks which ride on wheels situated in the chamber. The wheels 221 may be magnetic, in which case the tracks 224 may be made of paramagnetic material. In this embodiment the carrier is moved by linear motor 226, although other motive forces and/or arrangements may be used. Depositions source 272A is shown mounted onto one side of the chamber 240, while deposition source 272B is mounted on the other, opposite, side of the chamber. The carrier passes by deposition source 272, such that deposition is performed on the surface of the substrate as the substrate is moved passed the source.

FIG. 3 is a schematic illustration of one of sources 272A, 272B, as they appear looking head on from inside the chamber, as shown by arrows A-A in FIG. 2. In this arrangement, sputtering targets 305A, 305B, which in this example are comprised of conductive graphite, stand facially opposed each other at a separation distance “d” governed by the resultant magnetic field found in the mid-gap between the two. In this example, the targets abut heat sinks in the form of cooling plates 310A, 310B, in which cooling fluid, such as water, circulate.

Behind each target, a mounting plate, e.g., stainless steel plate 315A, 315B, is provided with magnets 320A, 320B. The magnets are arranged about the periphery of the mounting plate 315A, 315B, so that one of the magnetic pole is pointed towards the target. This can be seen more clearly from the phantom drawings shown in broken-line in FIG. 3. In FIG. 3, each magnet is shown shaded such that the darker side signifies a north magnetic pole and the lighter side signifies a south magnetic pole. In the example of FIG. 3, the magnets are arrange such that their magnetic pole is facing the target and is of opposite polarity of the corresponding magnet on the other target. That is, as can be seen in FIG. 3, magnets 320A have their lighter side, i.e., their south magnetic pole pointed towards target 305A, while the corresponding magnets 320B have their darker side, i.e., their north pole pointing towards target 305B.

Also, as shown in FIG. 3, according to embodiments of the invention, the magnets are arranged so as to define an axis height, h, and axis width, w, of the magnet array. The axis height and width are set such that the flattening factor is above 0.65. That is: flattening factor f=(h−w)/h, >0.65.

According to aspects of the invention, the separation “d” of the targets and the magnets' strength are selected according to a defined relationship so as to enable the formation of the desired film having the desired properties, especially density property. The separation distance “d” between the target pair is designed to be between 30 and 300 mm and preferably between 40 and 200 mm. The maximum magnet energy products for the individual magnets 320A, 320B, ranges between 200 kJ/m³<BHₘₐₓ<425 kJ/m³ and preferably 300 kJ/m³<BHₘₐₓ<400 kJ/m³, which yields an engineered electron orbit length of about one micron, sufficient for robust ionization. This combination of ranges has shown to enable the deposition of high quality DLC film.

The design of the embodiment described enables to maximize the cross section of ionizing electrons (for ionization of C, Ar, Kr, Ne, Xe, N₂, H₂, He, etc.) in the region between the sputter source and the substrate. In this way, subsequent films will be constructed primarily from an ionized carbon adsorbate, which, as previously described, promotes higher density DLC fabrication. Accordingly, it is within one's discretion whether they would optimize toward a nearer separation between targets and a lower magnetic field, or a wider separation and, potentially, a higher field. It is found in general, that collimation of the adsorbate engenders improved film quality as arriving atoms have a minimum of translational energy for incidences normal to the growth plane. With increasing translational energy, the adsorbing specie is capable of migrating across the film plane wherein it will likely find an energetically favorable sp² bonding opportunity thus rendering the film more graphitic. Therefore, one may choose a more narrow target-to-target spacing to provide better oblique collimation with the sacrifice in the form of a partial loss in deposition rate.

Some unforeseen advantages of the disclosed system arise in support of the novel capabilities discussed heretofore. Most importantly, the pressure of the working gas (e.g., Ar) required for plasma ignition is reduced by approximately one order of magnitude. Whereas standard balanced magnetron cathodes (e.g., an Intevac L-URMA™) requires approximately 1.0 Pa to generate a plasma, the cathode pair described in this disclosure needs only 0.1 Pa for ignition. This advantage is leveraged twofold: first by the increase in mean-free-path for the adsorbate specie and, hence, lower thermalization effect; and second, by the resulting decrease of working gas incorporated into the growing film.

Also of importance is the discovery that with the cathode design being such that the magnetic B-fields are largely tangential to the cathode, the resulting confinement of the electrons within the target space greatly reduces the plasma connection to the substrate. And since the substrate is then effectively remote of the working plasma, there is little to no heating of the substrate during deposition. This affords the process engineer greater luxury of process-design and specifically enables the decision to have heat present during growth or not. Most who optimize DLC growth for the recording media application tend toward lower substrate temperatures to inhibit translational mobility of adsorbing atoms. A follow on to this advantage of remote placement of substrate is a decreased sensitivity to vacuum environment. Because there is no perceptible plasma available in the vicinity of the substrate, there is a reduced concentration of free radicals adversely reacting with the growth specie(s) during the deposition. This has the generalized effect of improved economics through higher yields as fewer finished film structures are found to have contamination defects; and the ability to thereby relax costly standards of vacuum quality prior to production.

### Example I

In a first example, a plurality of 354 kJ/m³ magnets are placed upon a 410 stainless steel mounting plate, which is subsequently attached directly behind each target's heatsink. The outer ring of magnets all have the same polarity, and the opposite polarity to the magnet plate constructed for the opposing target. An optional field-bending magnet 323B is added at the center of the mounting plate, so as to bend the magnetic field generated by the outer ring of magnets 320B. This provides an improved confinement of the plasma. In this example, an equal or weaker magnet 323B (BHₘₐₓ≦354 kJ/m³) of opposite polarity of magnets 320B is interposed within the outer ring.

### Example II

A process to produce a viable magnetic recording disc has been developed, using the described magnetron. The process preceding the carbon overcoat step is generalized to include a series of front end cleaning operations and possible mechanical texturing in preparation for multilayer deposition, which is not particularly relevant to the method of the invention. Furthermore, it is assumed that the preceding steps occurring prior to carbon deposition include some combination of magnetic and non-magnetic materials (predominantly metals) and that the disc temperature heading into the carbon deposition station is in the range of 300-500 K. A ta-C carbon deposition then ensues with the cathode pairs (one about each side of the disc) such that each has a target pair separated by 50 mm, with peripheral magnets having north magnetic pole pointing towards the target and a center magnet having a south magnetic pole pointing towards the target. The target on the opposite side has the opposite magnetic arrangement, i.e., peripheral magnets having south magnetic pole pointing towards the target and a center magnet having a north magnetic pole pointing towards the target. The arrays are powered by 354 kJ/m³ NdFeB permanent magnets.

The substrate is initially located aft of the chamber centerline (of which the cathode pair(s) gap is co-located), such that it is not exposed to the sputtering. Prior to turning on the flow of argon, the chamber background pressure is <2×10⁻⁴ Pa. When the Ar-pressure is then stabilized at 0.1 Pa, the cathodes are powered on (by applying power of between 250 and 3500 W) and the substrate begins to travel past the cathode aperture to the fore of center position (as shown by the double-arrow in FIG. 3). The speed of travel is determined by the desired throughput of the overall system. This “scan” approach allows enhanced thickness uniformity for the final carbon film. When the substrate reaches the fore position, the power is turned off and the gas mass-flow-controllers (MFC) are closed allowing the chamber to regenerate the base condition for the next disc to be processed. The disc is then either exited from the system, or subjected to a further processing step to further condition the film surface. After removal from vacuum, the disc is then put through backend processing where it receives a thin lubricant layer, post-deposition polishing and flyability assurance testing.

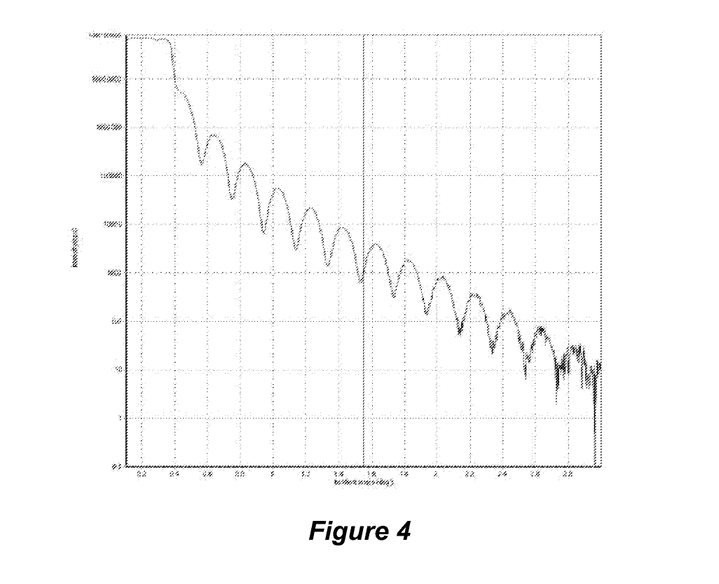

Shown in FIG. 4 is an x-ray reflectometry curve for a film grown in the abovementioned manner directly on a NiP/Al disc substrate. A fitting routines that combine known and unknown variables for the stack reveals a carbon film grown 22 nm thick, with a conformal roughness of 0.5 nm (the disc surface without carbon was also 0.5 nm), and a film density of 2.9 g/cm³. The competitive value of such a film would quickly be identified by one skilled in the art.

The resulting process carried out in the described apparatus provides high density carbon film (DLC) in the range of 2.4-3.5 g/cm³. In the described embodiments, the target and plasma are remote from the disk, so a highly ionized carbon atoms can be generated to result in high density carbon film. The magnetic field is lowered, thereby resulting in higher ionization cross-section. That is, the apparatus described herein uses remote plasma with low magnetic field to generate highly ionized carbon atoms. The facing targets as described confine the plasma. Low argon pressure can be used.

Finally, although this disclosure is written specifically for the application of DLC films, the same technology would be of benefit to a wide variety of other materials including metals, ceramics, and semiconductors. The additional control of growth kinetics when a substantial portion of the adsorbate is in ionized form enables thin film synthesis with greater flexibility in process design.

The present invention has been described in relation to particular examples, which are intended in all respects to be illustrative rather than restrictive. Those skilled in the art will appreciate that many different combinations of hardware, software, and firmware will be suitable for practicing the present invention. Moreover, other implementations of the invention will be apparent to those skilled in the art from consideration of the specification and practice of the invention disclosed herein. Various aspects and/or components of the described embodiments may be used singly or in any combination in the server arts. It is intended that the specification and examples be considered as exemplary only, with a true scope and spirit of the invention being indicated by the following claims.

1. A sputtering source comprising:
a vacuum chamber having an ion emission aperture;
a first sputtering target provided within the chamber and positioned such that its sputtering surface is oriented orthogonally to the aperture;
a second sputtering target provided within the chamber and positioned such that its sputtering surface is oriented orthogonally to the aperture and in a facing relationship to the first target and at a distance d from the first target;
a plasma power applicator for igniting and sustaining plasma within the chamber in the space between the first target and the second target;
a first magnet array positioned behind the first target and having a plurality of magnets oriented with the south pole pointing towards the first target;
a second magnet array positioned behind the second target and having a plurality of magnets oriented with the north pole pointing towards the second target.

2. The sputtering source of claim 1, wherein the distance d is between 30 and 300 mm.

3. The sputtering source of claim 1, wherein the distance d is between 40 and 200 mm.

4. The sputtering source of claim 1, wherein the maximum magnet energy products for the individual magnets of the first and second magnet arrays ranges between 200 kJ/m³<BHₘₐₓ<425 kJ/m³.

5. The sputtering source of claim 1, wherein the maximum magnet energy products for the individual magnets of the first and second magnet arrays ranges between 300 kJ/m³<BHₘₐₓ<400 kJ/m³.

6. The sputtering source of claim 1, wherein the distance d is between 30 and 300 mm and the maximum magnet energy products for the individual magnets of the first and second magnet arrays ranges between 200 kJ/m³<BHₘₐₓ<425 kJ/m³.

7. The sputtering source of claim 1, wherein the distance d is between 40 and 200 mm and the maximum magnet energy products for the individual magnets of the first and second magnet arrays ranges between 300 kJ/m³<BHₘₐₓ<400 kJ/m³.

8. The sputtering source of claim 1, wherein each of the first and second magnet arrays further comprises a secondary magnet positioned in the center of the corresponding magnet array and oriented at opposite polarity of the magnets in the corresponding magnet array.

9. The sputtering source of claim 8, wherein the magnetic strength of the secondary magnet is not higher than magnetic strength of any magnet in the corresponding magnet array.

10. The sputtering source of claim 1, wherein the magnets in each of the first and second magnet arrays are arranged so as to define an axis height, h, and axis width, w, set such that the flattening factor (f=(h−w)/h) is above 0.65.

11. A deposition system for depositing a layer onto a substrate, comprising:
a processing chamber;
a first sputtering source provided on one side of the processing chamber;
a second sputtering source provided on the opposite side if the processing chamber;
a transport mechanism provided within the processing chamber to scan the substrate while the first and second sputtering sources are energized;
wherein each of the first and second sputtering sources comprises:
a vacuum chamber having an ion emission aperture directed towards the processing chamber;
a first sputtering target provided within the vacuum chamber and positioned such that its sputtering surface is oriented orthogonally to the aperture;
a second sputtering target provided within the vacuum chamber and positioned such that its sputtering surface is oriented orthogonally to the aperture and in a facing relationship to the first target and at a distance d from the first target;
a plasma power applicator for igniting and sustaining plasma within the vacuum chamber and confining the plasma in the space between the first target and the second target;
a first magnet array positioned behind the first target and having a plurality of magnets oriented with the south pole pointing towards the first target;
a second magnet array positioned behind the second target and having a plurality of magnets oriented with the north pole pointing towards the second target.

12. The system of claim 11, wherein the distance d is between 30 and 300 mm.

13. The system of claim 11, wherein the distance d is between 40 and 200 mm.

14. The system of claim 11, wherein the maximum magnet energy products for the individual magnets of the first and second magnet arrays ranges between 200 kJ/m³<BHₘₐₓ<425 kJ/m³.

15. The system of claim 11, wherein the maximum magnet energy products for the individual magnets of the first and second magnet arrays ranges between 300 kJ/m³<BHₘₐₓ<400 kJ/m³.

16. The system of claim 11, wherein the distance d is between 30 and 300 mm and the maximum magnet energy products for the individual magnets of the first and second magnet arrays ranges between 200 kJ/m³<BHₘₐₓ<425 kJ/m³.

17. The system of claim 11, wherein the distance d is between 40 and 200 mm and the maximum magnet energy products for the individual magnets of the first and second magnet arrays ranges between 300 kJ/m³<BHₘₐₓ<400 kJ/m³.

18. A method for physical vapor deposition on a substrate, comprising:
forming a plasma cage within a vacuum chamber and exposing an emission aperture of the vacuum chamber into a processing chamber while confining the plasma to the vacuum chamber;
transporting the substrate in front of the aperture while ions are emitted from the aperture.

19. The method of claim 18, wherein forming a plasma cage comprises:
positioning a first sputtering target within the vacuum chamber such that its sputtering surface is oriented orthogonally to the aperture;
positioning a second sputtering target within the vacuum chamber such that its sputtering surface is oriented orthogonally to the aperture and in a facing relationship to the first target and at a distance d from the first target;
providing a plasma power applicator for igniting and sustaining plasma within the vacuum chamber and confining the plasma in the space between the first target and the second target;
positioning a first magnet array behind the first target such that a plurality of magnets of the first magnet array are oriented with the south pole pointing towards the first target;
positioning a second magnet array behind the second target such that a plurality of magnets of the second magnet array are oriented with the north pole pointing towards the second target.

20. The system of claim 19, wherein the distance d is selected from between 40 and 200 mm and the maximum magnet energy products for the individual magnets of the first and second magnet arrays is selected between 300 kJ/m³<BHₘₐₓ<400 kJ/m³.
